(19) United States
(12) Patent Application Publication
(10) Pub. No.: US 2013/0094273 A1
(43) Pub. Date: Apr. 18, 2013

(54) 3D MEMORY AND DECODING TECHNOLOGIES

(71) Applicants: WEI-CHIH CHIEN, TAIPEI (TW); MING-HSIU LEE, HSINCHU (TW); HSIANG-LAN LUNG, ARDSLEY, NY (US)

(72) Inventors: WEI-CHIH CHIEN, TAIPEI (TW); MING-HSIU LEE, HSINCHU (TW); HSIANG-LAN LUNG, ARDSLEY, NY (US)

(21) Appl. No.: 13/706,001

(22) Filed: Dec. 5, 2012

Related U.S. Application Data
(63) Continuation-in-part of application No. 12/755,325, filed on Apr. 6, 2010.
Application No. 12/755,325 is a continuation-in-part of application No. 12/785,291, filed on May 21, 2010.
(60) Provisional application No. 61/726,987, filed on Nov. 15, 2012.

(51) Int. Cl. G11C 5/06

(52) U.S. Cl. CPC G11C 5/06; H01L 28/24
USPC 365/63; 438/382

(57) ABSTRACT

A 3D memory device is based on an array of conductive pillars and a plurality of patterned conductor planes including left side and right side conductors adjacent the conductive pillars at left side and right side interface regions. Memory elements in the left side and right side interface regions comprise a programmable transition metal oxide which can be characterized by built-in self-switching behavior, or other programmable resistance material. The conductive pillars can be selected using two-dimensional decoding, and the left side and right side conductors in the plurality of planes can be selected using decoding on a third dimension, combined with left and right side selection.

### RELATED APPLICATIONS

This application is a continuation-in-part of U.S. application Ser. No. 12/755,325 filed on 6 Apr. 2010 (MXIC 1913-1); and is a continuation-in-part of U.S. application Ser. No. 12/785,291 filed on 21 May 2010 (MXIC 1914-1); and claims the benefit of U.S. Provisional Patent Application No. 61/726,987 filed on 15 Nov. 2012.

### BACKGROUND OF THE INVENTION

1. Field of the Invention

The present invention relates to high density memory devices, and particularly to memory devices in which multiple planes of memory cells are arranged to provide a three-dimensional 3D array.

2. Description of Related Art

As critical dimensions of devices in integrated circuits shrink to the limits of common memory cell technologies, designers have been looking to techniques for stacking multiple planes of memory cells to achieve greater storage capacity, and to achieve lower costs per bit. For example, cross-point array techniques have been applied for anti-fuse memory in Johnson et al., “512-Mb PROM With a Three-Dimensional Array of Diode/Anti-fuse Memory Cells” IEEE J. of Solid-State Circuits, vol. 38, no. 11 November 2003. In the design described in Johnson et al., multiple layers of word lines and bit lines are provided, with memory elements at the cross-points. The memory elements comprise a p+ polysilicon anode connected to a word line, and an n-polysilicon cathode connected to a bit line, with the anode and cathode separated by anti-fuse material.

In the processes described in Johnson et al., there are several critical lithography steps for each memory layer. Thus, the number of critical lithography steps needed to manufacture the device is multiplied by the number of layers that are implemented. Critical lithography steps are expensive, and so it is desirable to minimize them in manufacturing integrated circuits. So, although the benefits of higher density are achieved using 3D arrays, the higher manufacturing costs limit the use of the technology.

One technology for 3D anti-fuse memory is described in co-pending U.S. Patent Application entitled INTEGRATED CIRCUIT 3D MEMORY ARRAY AND MANUFACTURING METHOD, application Ser. No. 12/430,290, filed 27 Apr. 2009, which is incorporated by reference as if fully set forth herein.

It is desirable to provide a structure for three-dimensional integrated circuit memory with high density and low manufacturing cost, including reliable, very small memory elements.

### SUMMARY OF THE INVENTION

A memory device on an integrated circuit is described that includes a 3D memory array of two-cell unit structures including programmable and erasable resistance elements. The 3D array includes a plurality of patterned conductor layers separated from each other by insulating layers. An array of access devices is included on the integrated circuit arranged to provide access to individual conductive pillars which extend into the 3D array. The patterned conductive layers include left side and right side conductors adjacent the conductive pillars. This defines the left side and right side interface region between the conductive pillars and adjacent left side and right side conductors. Memory elements are provided in the left side and right side interface regions, each of which comprises a programmable and erasable element and if needed, a rectifier or other switch. In examples described herein, the programmable element comprises a transition metal oxide, characterized by built in self switching, and can thereby provide both the memory element and switch functions.

A device as described herein can include row decoder circuits and column decoder circuits coupled to the array of access devices, and arranged to select an individual conductive pillar in the array of conductive pillars. Also, left and right plane decoding circuits are coupled to the left side and right side conductors in the plurality of patterned conductor layers. Decoding circuits are arranged to apply a bias to cause current flow in a selected cell, in a left side or right side interface region in a selected patterned conductor layer, and to reverse bias the rectifier to an unselected cell.

In a structure described herein, the conductive pillars in the array can comprise a semiconductor material having a first conductivity type in electrical communication with a corresponding access device. Also, the left side and right side conductors comprise a semiconductor material having a second conductivity type, so that the rectifier in each of the memory elements comprises a p-n junction. In other embodiments, the conductive pillars comprise metal or combinations of metals and other conductive or semiconductive materials.

The left side and right side conductors in each layer have landing areas that are not overlaid by any of the left side and right side conductors in overlying patterned conductor layers. Conductive lines such as metal plugs extend through vias to the plurality of patterned conductor layers and contact the landing areas. Left side and right side connectors in a patterned metallization layer for example, and over the plurality of patterned conductor layers, connect with the conductive lines in the vias and provide for connection to the decoding circuitry.

A method for manufacturing a memory device is described as well. The plurality of patterned conductor layers can be formed by first forming a plurality of blanket layers of conductive material with blanket layers of insulating material between the blanket layers of conductive material to form a stack. Then, the stack is etched to define the left side and right side conductors, such as by forming trenches in the stack. A layer of the memory material is deposited or formed on the side walls of the trenches, and then the trenches are filled with a conductive material, such as a doped semiconductor. Next, the conductive material is patterned within the trench to form the conductive pillars. Insulating material is then filled in between the pillars.

A memory cell is programmed by applying voltage bias between the conductive pillar and a selected left side or right side conductor line in the desired plane to program a programmable resistance memory element, in the interface region. A rectifier, established by the p-n junction in the interface region or otherwise, provides isolation between memory cells on different layers within the pillar. When the memory element has a threshold characteristic, the switching function can be provided by the memory element itself, without need for additional components to provide the rectifying or switching function for the memory cells.

Other aspects and advantages of the present invention can be seen on review of the drawings, the detailed description and the claims, which follow.

### BRIEF DESCRIPTION OF THE DRAWINGS

FIG. 1 is a schematic illustration showing an X-Z slice view of a 3D memory structure, as described herein.

FIG. 2 is a schematic illustration showing an X-Y level view of a 3D memory structure, as described herein.

FIG. 3A shows the structure of a two-cell unit structure along with the symbol for the unit cell utilized in FIG. 1 and FIG. 2 of the 3D memory structure.

FIG. 3B shows a side view of two levels of memory cells on a pillar, in one example implementation.

FIG. 4 is a perspective drawing of a portion of a 3D memory structure described herein.

FIG. 5 is a cross-sectional view in the Y-Z plane of the structure in FIG. 4.

FIGS. 6-11 show a sequence of stages of a manufacturing process for making the 3D memory structure described herein.

FIG. 12 is a layout view in the X-Y plane of a 3D memory structure described herein.

FIG. 13 illustrate a layout view of a forked left/right conductor structure with shared pad structures.

FIG. 14 illustrates implementation of a representative pillar access device array in a substrate.

FIG. 15 is a graph showing an IV curve for a metal oxide memory element.

FIG. 16 shows a side view of two levels of memory cells on a pillar, in one alternative example implementation.

FIG. 17 is a schematic illustration of a level and left/right decoder for one example implementation.

FIG. 18 is a schematic illustration of a level and left/right decoder for another example implementation.

FIG. 19 is a simplified block diagram of an integrated circuit including a 3D, two-cell unit structure memory array.

### DETAILED DESCRIPTION

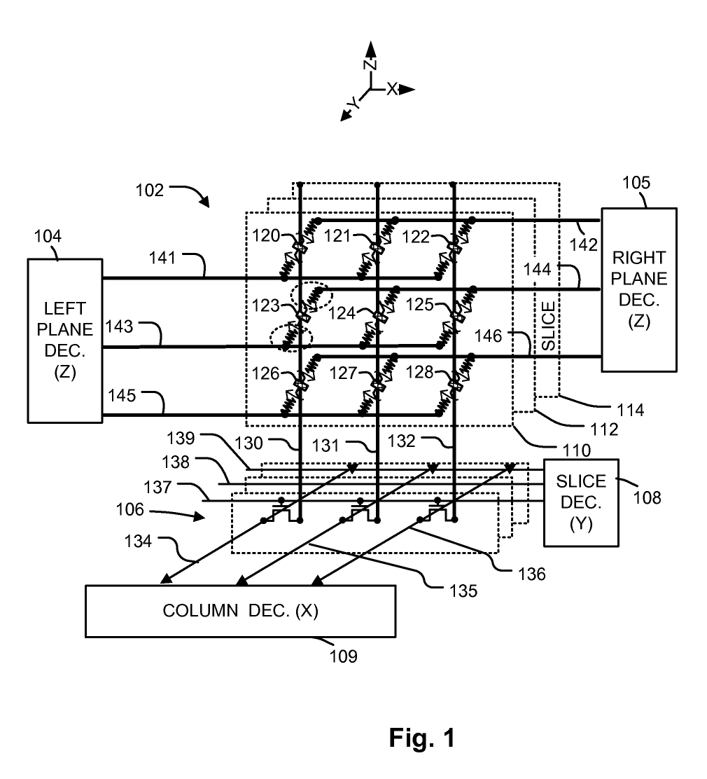

A detailed description of embodiments of the present invention is provided with reference to the FIGS. 1-19.

FIG. 1 is a schematic diagram of a 3D memory device, showing “slices” 110, 112, 114 which lie in X-Z planes of the 3D structure. In the illustrated schematic, there are nine two-cell unit structures 120-128, each unit structure having two memory cells having separate programmable elements and left and right terminals. Embodiments of the 3D memory device can include many two-cell unit structures per slice. The device includes an array of cells arranged for left and right decoding, using a left plane decoder 104, right plane decoder 105, and pillar access device array 106. The conductive pillars of the two-cell unit structures in a Z-direction column (e.g. 120, 123, 126) are coupled via a conductive pillar (e.g. 130) to an access device in a pillar access device array 106, implemented for example in the integrated circuit substrate beneath the structure. Likewise, the pillars for the two-cell unit structures 121, 124, 127 are coupled via a conductive pillar 131 to a corresponding access device in the pillar access device array 106. The pillars for the two-cell unit structures 122, 125, 128 are coupled via the conductive pillar 132 to the pillar access device array 106.

The left side word line conductors (e.g. 141) on the two-cell unit structures in a particular level (e.g. structures 120, 121, 122) in all of the slices 110, 112, 114 are coupled to a driver selected by left plane decoder 104. Likewise, the right side word line conductors (e.g. 142) on the two-cell unit structures in a particular level (e.g. 120, 121, 122) in all of the slices 110, 112, 114 are coupled to a driver selected by right plane decoder 105. The left side word line conductor 143 and right side word line conductor 144 on the level including two-cell unit structures 123, 124 125 are coupled to the left plane decoder 104 and to the right plane decoder 105, respectively. The left side word line conductor 145 and right side word line conductor 146 on the level including two-cell unit structures 126, 127, 128 are coupled to the left plane decoder 104 and to the right plane decoder 105, respectively.

The two-cell unit structures 120-128 include a programmable element, such as a transition metal oxide, and if needed, a switch such as a rectifier for each cell, as indicated in schematic form in FIG. 1. The memory cell can be composed of materials such as a metal oxide like those known as ReRAM, including tungsten oxide, titanium oxide, nickel oxide, aluminum oxide, copper oxide, zirconium oxide, niobium oxide, tantalum oxide titanium nitride oxide, chromium doped SrZrO₃, chromium doped SrTiO₃, PCMO, LaCaMnO and so on.

The memory cells can also be composed of other two-terminal resistance-change memory devices (phase change memory, conduction bridge memory, spin torque transfer memory (STT memory), etc.)

The pillar and left and right side conductors can be composed of conductive metal or metal-like materials including for example, TiN, Yb, Tb, Y, La, Sc, Hf, Zr, Al, Ta, Ti, Nb, Cr, V, Zn, W, Mo, Cu, Re, Ru, Co, Ni, Rh, Pd, Pt, W and various compounds and alloys of these materials. Also, semiconductors may be used in some embodiments.

The switch element for the memory cells can be composed of a metal-oxide diode, a tunneling diode, or other diode structure, and by using the non-linear IV correlation of the memory cell for built-in self-switching, as described below. More details of a two-cell unit structure are provided below.

As can be seen, a current path for reading an individual cell (e.g. one of the two cells in unit structure 123) is established by applying a voltage to cause current flow between the corresponding pillar (e.g. pillar 130) and a selected one of the left side and right side conductors on a selected plane (e.g. one of conductors 143 and 144), while blocking current flow in other cells in the array.

Bottom ends of the array of conductive pillars of the two-cell unit structures 120-128 in a Z-direction column (e.g. 120, 123, 126) are coupled via a corresponding pillar 130, 131, 132 to a corresponding access device in pillar access device array 106, implemented for example in the integrated circuit substrate beneath the structure.

The access devices in the pillar access device array 106 selectively couple a Z-direction column of the two-cell unit structures 120-128 to a corresponding bit line in a plurality of bit lines 134, 135, 136 extending in the Y-direction. The bit lines in the plurality of bit lines 134, 135, 136 are coupled to a column decoder 109.

The gates of the transistors in pillar access device array 106 are coupled to select lines 137, 138, 139 extending in the X-direction. The select lines 137, 138, 139 are coupled to slice decoder 108.

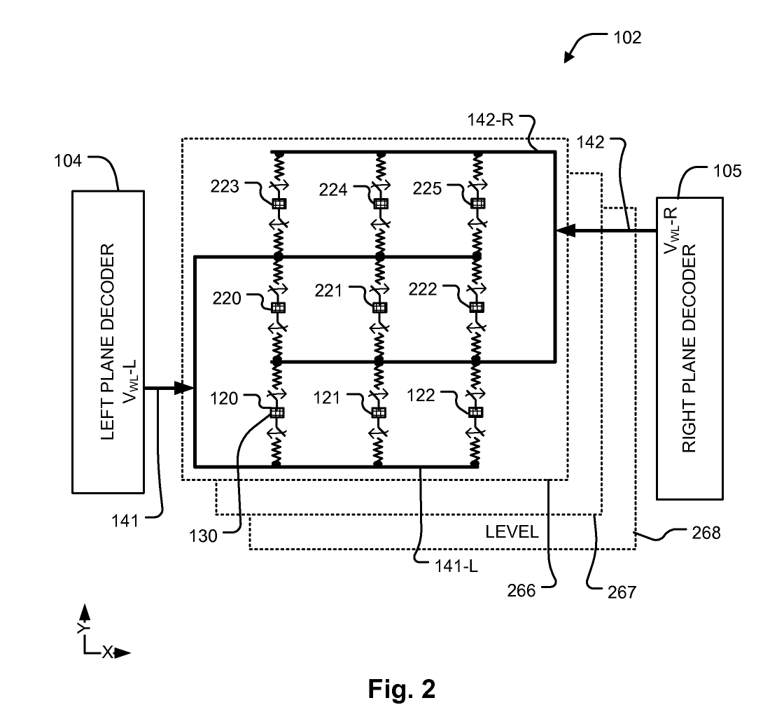

FIG. 2 is a schematic diagram of a 3D memory device, showing “levels” 266, 267, 268, which lie in X-Y planes of the 3D structure. The left plane decoder 104 and right plane decoder 105 are illustrated in the figure. Each level in the schematic includes nine two-cell unit structures. Embodiments can include many cells per level. The front row of unit structures in level 266 in the schematic includes two-cell unit structures 120, 121, 122, corresponding to the top row in the slice shown in FIG. 1. The balance of the two-cell unit structures 220-225 shows 3-by-3, X-Y arrangement of unit structures on the level, although the array can be much larger, including for example 1000×1000 two-cell units on each plane, or more. As shown in FIG. 2, the left conductor element 141 is arranged to connect to the left side conductors between alternating pairs of rows using a forked conductor 141-L. Likewise, the right left conductor element 142 is interleaved with the left conductor element 141, and arranged to connect to the right side conductors between the other alternating pairs of rows using forked conductor 142-R. As described below, the left and right side conductors may be separated from one another in each plane, and connected by vias to overlying connectors (rather than forked and connected together in the plane as shown).

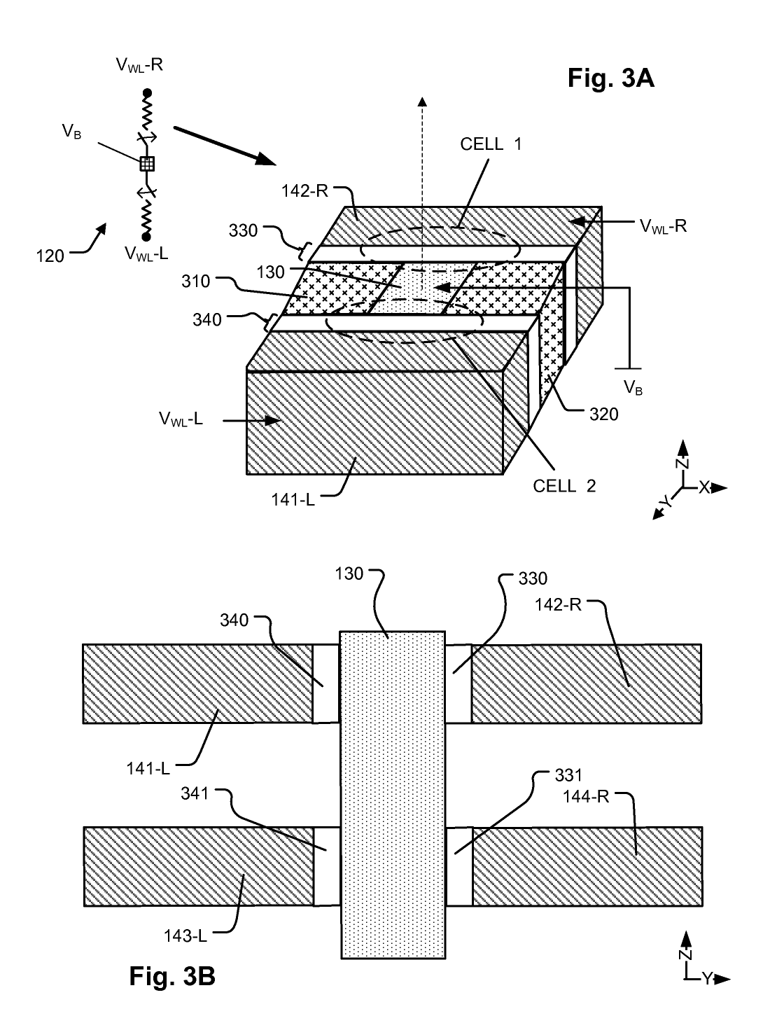

The two-cell unit structure is shown in FIG. 3A. The symbol 120 which is utilized in FIG. 1 and FIG. 2 representing the unit structure can be represented by the structure shown, including left side conductor 141-L, right side conductor 142-R, and the conductive pillar 130. Dielectric insulators 310 and 320 separate the pillars. The memory elements 330, 340 comprise layers of programmable material on opposing sides of the conductive pillar 130 and between respective surfaces on opposing sides of the conductive pillar 130 and the corresponding left side and right side conductors, 141-L or 142-R. Thus, two memory cells are provided by this unit structure, including CELL 1 and CELL 2 as labeled in the drawing, each cell including a programmable element and a rectifier.

The conductor lines 141-L and 142-R for this example can comprise a transition metal, such as tungsten, while the conductive pillar 130 comprises a conductor such as a metal, a metal nitride, a doped polysilicon and other conductors. In some implementations, a p-n junction rectifier for the memory cell is disposed in the interface region using p- and n-type semiconductors on opposing sides of the memory element.

A rectifier can be implemented by the p-n junction between the conductor line and the pillar. For example, a rectifier based on a solid electrolyte like for example germanium silicide, or other suitable material, could be used to provide a rectifier. See U.S. Pat. No. 7,382,647 by Gopalakrishnan for other representative solid electrolyte materials.

The memory cells are formed in the interface regions at cross-points of the pillar 130 and the left side and right side conductors, 141-L or 142-R, and can comprise a side wall layer of tungsten oxide or other metal oxide, such as those mentioned above. In the other embodiments, other memory elements may be utilized, including anti-fuse memory cells comprising a silicon dioxide, silicon oxynitride or other silicon oxide, for example having a thickness on the order of 5 to 10 nanometers, and a high resistance. Other anti-fuse materials may be used, such as silicon nitride, aluminum oxide, tantalum oxide, magnesium oxide and so on.

Bias voltages applied to the unit structures include the right word line voltage V_{WL}-R, the left word line voltage V_{WL}-L, and the pillar voltage V_{B}.

FIG. 3B shows a side view of two unit cells in two levels of the 3D array, where the top two-unit cell includes left side conductor 141-L and side wall memory element 340 connected to the pillar 130, and memory element 330 on the opposing side of the pillar 130, and right side conductor 142-R. The two-unit cell in the second level includes a two-unit cell including left side conductor 143-L and side wall memory element 341 connected to the pillar 130, and memory element 331 on the opposing side of the pillar 130, and right side conductor 144-R. In some implementations, there can be more than two levels, such as eight levels, sixteen levels and so on. The memory element 340 is over the memory element 341, both of which are disposed on a sidewall of the pillar 130. Likewise, memory element 330 is over memory element 331, both of which are disposed on a sidewall of the pillar 130.

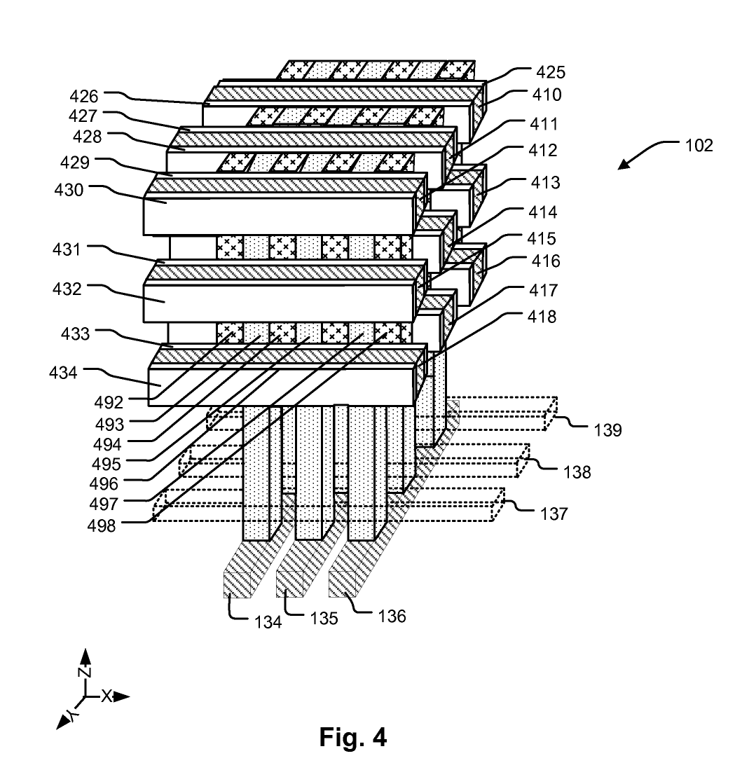

FIG. 4 shows a portion of a 3D structure including an array of memory cells as described with reference to FIGS. 1-3. Three patterned conductor layers are illustrated, where a top level includes patterned conductors 410-412 extending in the X-direction, a next lower level includes patterned conductors 413-415, and a next level includes patterned conductors 416-418. Programmable elements in this example are in the metal oxide structures 425-430 formed on the opposing sides of the patterned conductors 410-412 on the top level. Programmable elements are in the metal oxide structures 431-432 formed on opposing sides of patterned conductor 415, and programmable elements are in the metal oxide structures 433-434 formed on opposing side of patterned conductor 418. Similar programmable elements are formed on the sides of the other patterned conductors in the structure as well. The structure includes an array of conductive pillars, including pillars 81-84 in the back of the structure shown, and pillars 493, 495 and 497 on the front of the structure shown. Between and on opposing sides of the conductive pillars, insulating pillars are formed. Thus, insulating pillars 492, 494, 496 and 98 are shown on opposing sides of the conductive pillars 493, 495 and 497.

In FIG. 4, an alternative implementation for access transistors is shown, which requires that the pillars comprise doped semiconductor, and act as channel regions for vertical select transistors. The select lines 137, 138, 139, acting as gates for select transistors, underlie the memory cube 102 and extend in the X-direction. The conductive pillars extend through the select lines 137, 138 and 139 to the bit lines 134, 135 and 136 extending in the Y-direction. In other embodiments, the select transistors can be formed in source/drain terminals and channels in the substrate, or otherwise.

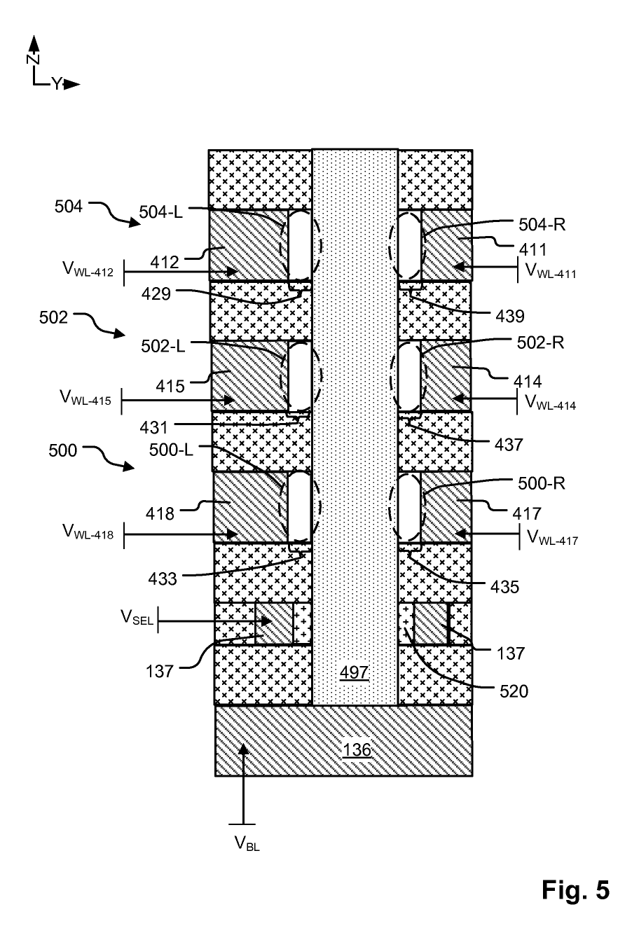

FIG. 5 is a cross-sectional view in the Y-Z plane of the structure in FIG. 4 showing the two-cell unit structures 500, 502, 504 along a Z-direction column which includes the semiconductor pillar 497. The reference numerals in FIG. 4 are repeated in FIG. 5 where appropriate.

The two-cell unit structure 500 includes a left cell 500-L and a right cell 500-R. The left cell 500-L includes conductor 418 and a metal oxide structure 433 as the memory element. The right cell 500-R includes conductor 417 and the metal oxide structure 435 as the memory element.

The two-cell unit structure 502 includes a left cell 502-L and a right cell 502-R. The left cell 502-L includes conductor 415 and the metal oxide structure 431 as the memory element. The right cell 502-R includes conductor 414 and metal oxide structure 437 as the memory element.

The two-cell unit structure 504 includes a left cell 504-L and a right cell 504-R. The left cell 504-L includes conductor 412 and the metal oxide structure 429 as the memory element. The right cell 504-R includes conductor 411 and the metal oxide structure 439 as the memory element.

Each of the levels of word lines are separated by insulating material, such as silicon nitride or silicon dioxide. Thus, two Z-direction columns of cells are provided by the two-cell unit structures 500, 502, 504.

The select line 137 surrounds the pillar 497, and extends into and out of the cross-section illustrated in FIG. 5. Gate dielectric 520 separates the select line 137 from the pillar 497.

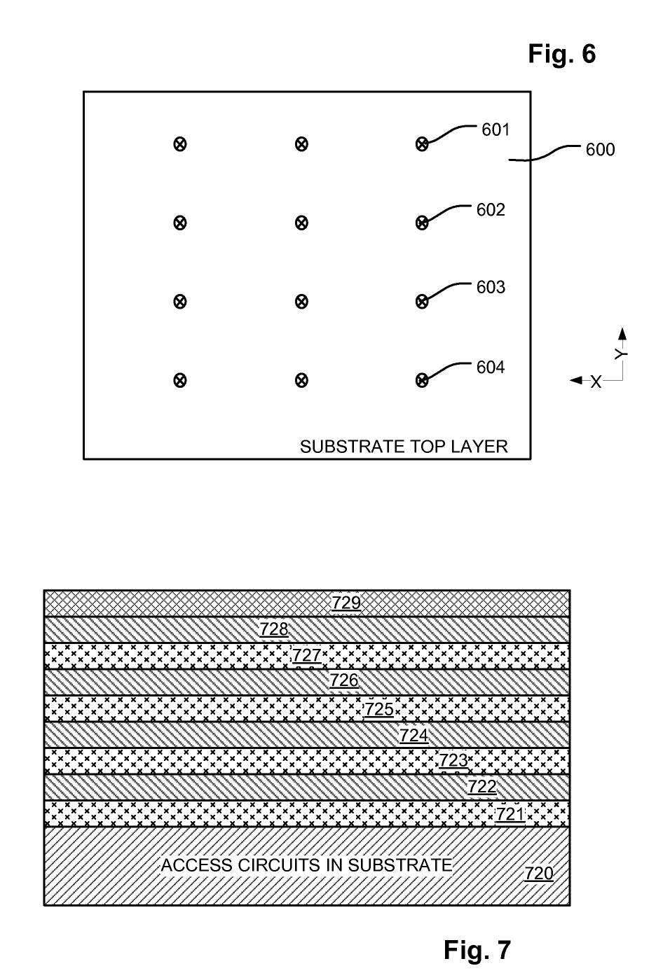

FIGS. 6-12 illustrate stages in a process for manufacturing the structure discussed above. In FIG. 6, a surface 600 of an integrated circuit substrate is illustrated with an array of contacts for connection to the 3D structure. The array of contacts includes contacts (e.g. 601-604) which are coupled to individual access devices, and adapted for connection to the conductive pillars in the 3D structure. The individual access devices can be formed in the substrate, and may include for example MOS transistors having gates coupled to word lines arranged in the X-direction, sources coupled to the source lines arranged in the Y-direction, and drains connected to the contacts (e.g. 601-604). The individual access devices are selected by biasing the word lines and source lines as appropriate for the particular operation. In some implementations, the access devices can comprise vertical, surrounding gate transistors, in which an upper source/drain terminal is coupled to the conductive pillar.

FIG. 7 is a side cross-section showing a multilayer stack of materials at a first stage in the manufacturing process, after forming alternating layers 721, 723, 725, 727 of insulating material, such as silicon dioxide or silicon nitride, and layers 722, 724,726, 728 of conductor material, such metals like tungsten, as n+-polysilicon, other doped semiconductor, metal nitrides or combinations of metals and other conductors like metal nitrides, on top of the substrate 720. In a representative structure, the thicknesses of the alternating layers of insulating material can be about 50 nanometers, and the thicknesses of the alternating layers of conductor material can be about 50 nanometers. Over the top of the alternating layers, a layer 729 of hard mask material, such as silicon nitride, can be formed.

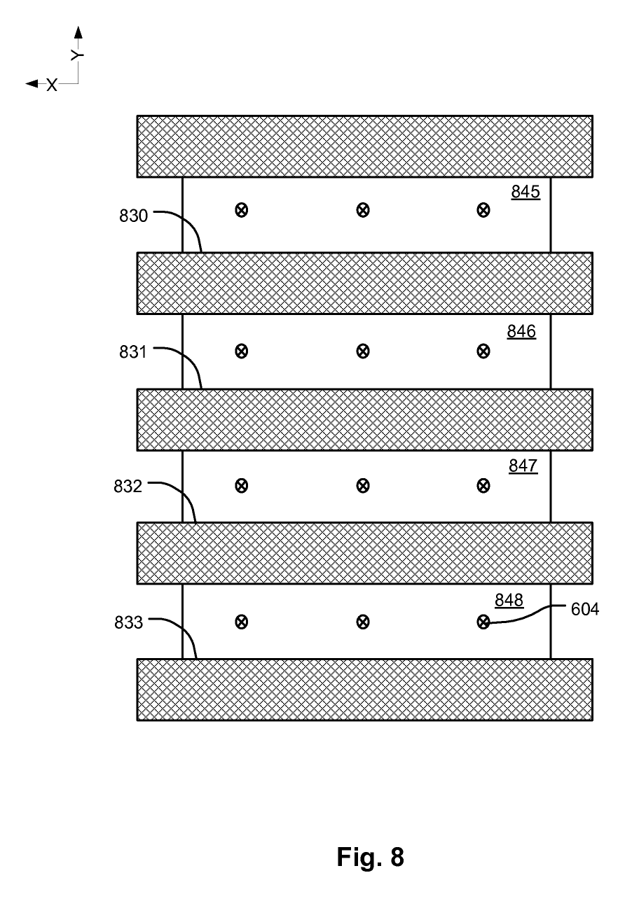

FIG. 8 is a layout view showing the results using a first lithographic process to define a pattern for the trenches, and a patterned etch of the stack to form trenches 845-848 through the multilayer stack of materials shown in FIG. 6, exposing contacts, such as contact 604, coupled to individual access devices in the pillar access circuits. Anisotropic reactive ion etching techniques can be used to etch through the conductive layers and silicon oxide or silicon nitride layers, with a high aspect ratio. The trenches have sidewalls 830-833 on which the layers of conductor material are exposed at each level of the structure. The widths of the trenches 845-848 in a representative structure can be about 70 nanometers for one example.

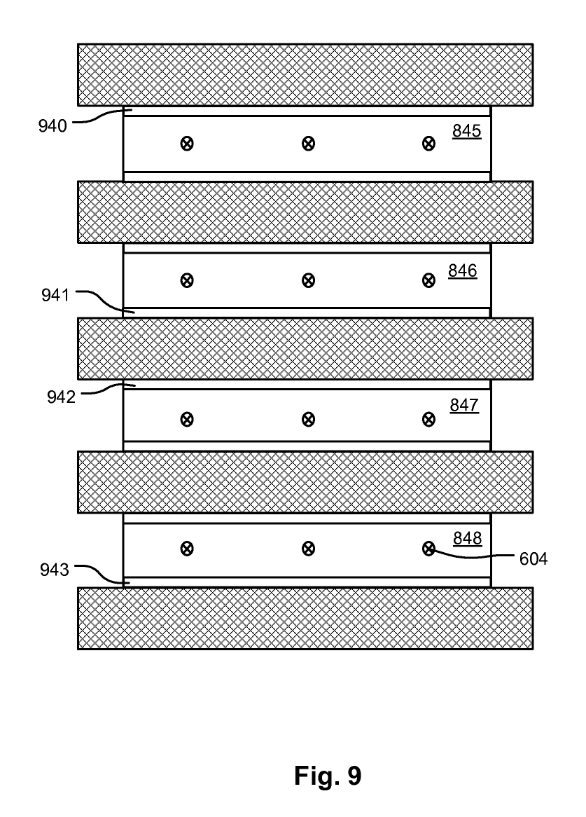

FIG. 9 shows a later stage in the process after formation of a layer of metal oxide memory material (940-943) on the sidewalls of the trenches (845-848) contacting the layers of conductor material. The metal oxide memory material may be formed by deposition, or by oxidation of the metal used for the conductive layers, when for example the conductive layers comprise tungsten or other metals suitable for formation of metal oxide memory materials. After formation of the metal oxide memory material, the process can include depositing a thin protective layer, such as p-type polysilicon over the metal oxide material, and etching the resulting formation using an anisotropic process to remove any memory material from the bottom of the trenches, 845-848, and exposing the contacts (e.g. 604).

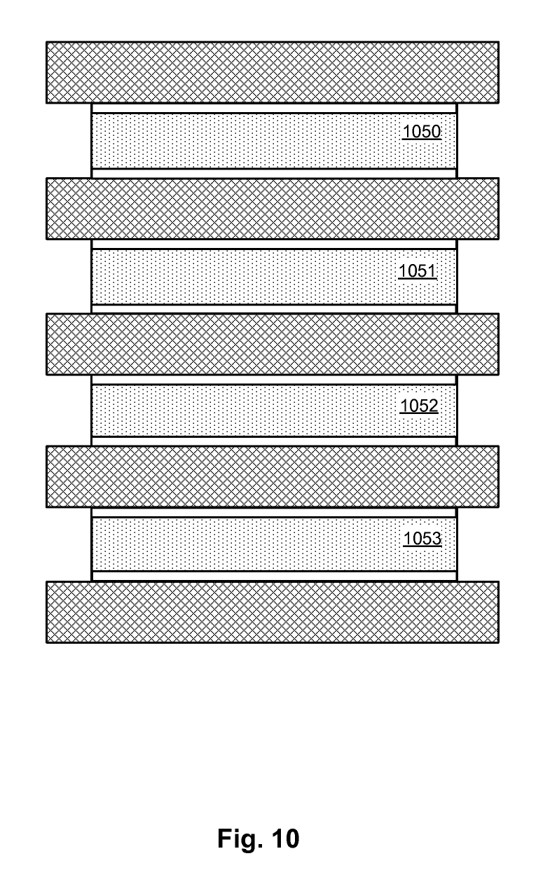

FIG. 10 shows a next stage in the process after filling the trenches with the material to be used for the conductive pillars, such as p-type polysilicon or a metal, to form filled trenches 1050-1053, between patterned conductors. In alternative structures, the trenches can be first lined using a doped semiconductor, and then filled using a metal, to improve conductivity of the structure, providing a rectifier in the interface region.

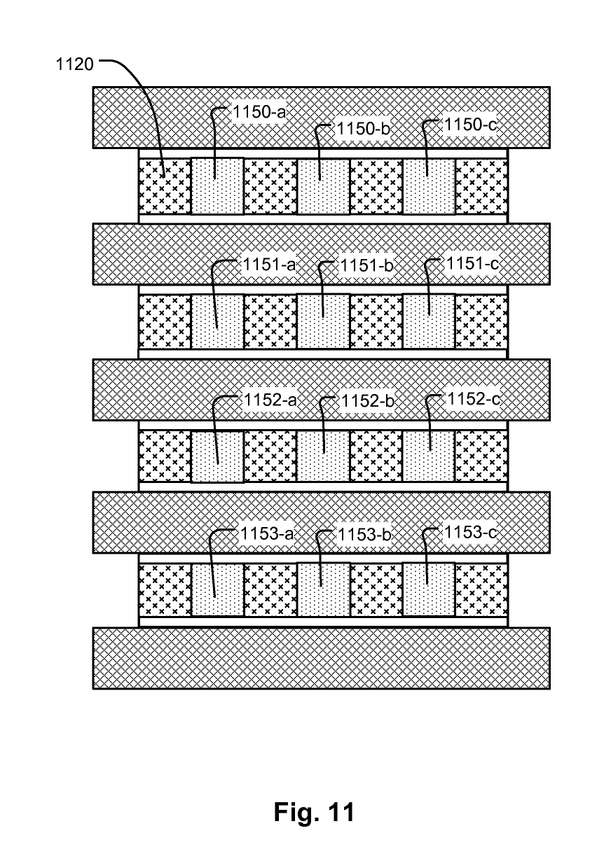

FIG. 11 shows the result of using a second lithographic process to define a pattern for the conductive pillars. A patterned etch of the filled trenches is applied using an anisotropic etch process that is selective for the material of the conductive pillars, to define the conductive pillars (1150-a, 1150-b, 1150-c, 1151-a, 1151-b, 1151-c, 1152-a, 1152-b, 1152-c, 1153-a, 1153-b, 1153-c) in contact with the contacts, including contact 604 (not shown, see FIGS. 8 and 9), to the underlying individual access devices, and to create vertical openings between the conductive pillars. Next, dielectric insulating material, such as silicon dioxide, is filled in between the pillars to form insulator columns (e.g. insulator 1120) between the pillars.

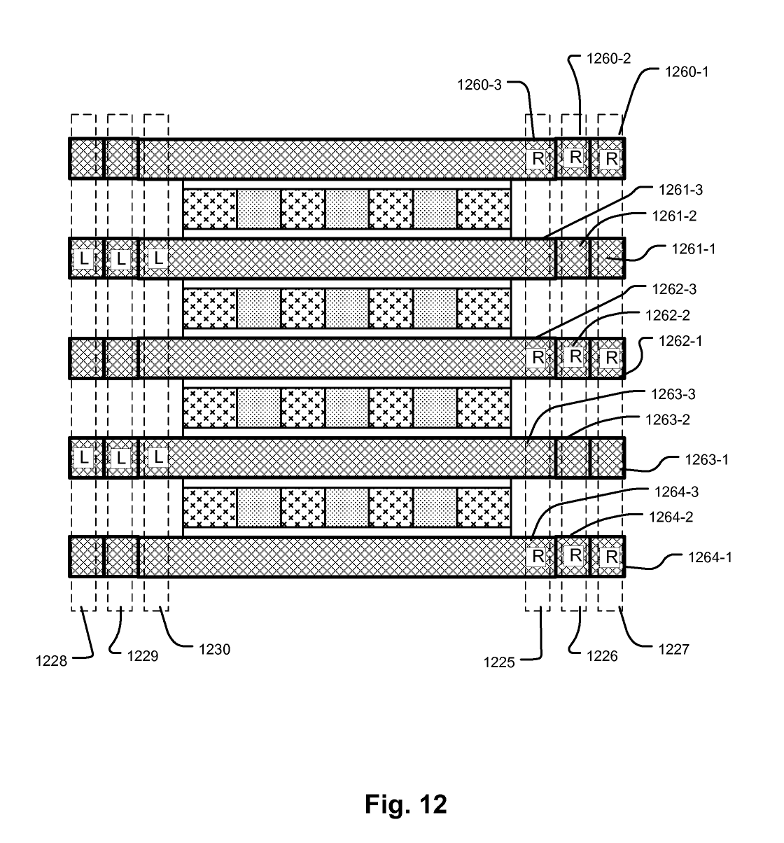

FIG. 12 illustrates a top view of a configuration for making contact to the left side and right side conductor lines in the plurality of planes. The left side conductors 1261-1, 1261-2, 1261-3 and 1263-1, 1263-2, 1263-3 and right side conductors 1260-1, 1260-2, 1260-3, 1262-1, 1262-2, 1262-3 and 1264-1, 1264-2 , 1264-3 in each layer have landing areas (labeled “L” or “R”) arranged in a stair-step pattern (or other pattern) so that the landing areas in each level are not overlaid by any of the left side and right side conductors in overlying patterned conductor layers. Contact plugs or other conductive lines (not shown) extend through the plurality of conductor layers and contact the landing areas. An overlying patterned connection layer includes left side connectors 1228, 1229, 1230 and right side connectors 1225, 1226, 1227 over the plurality of patterned conductor layers and in contact with the conductive lines contacting the landing areas of left and right side conductors. The left side and right side connectors are routed to left and right plane decoding circuits (not shown).

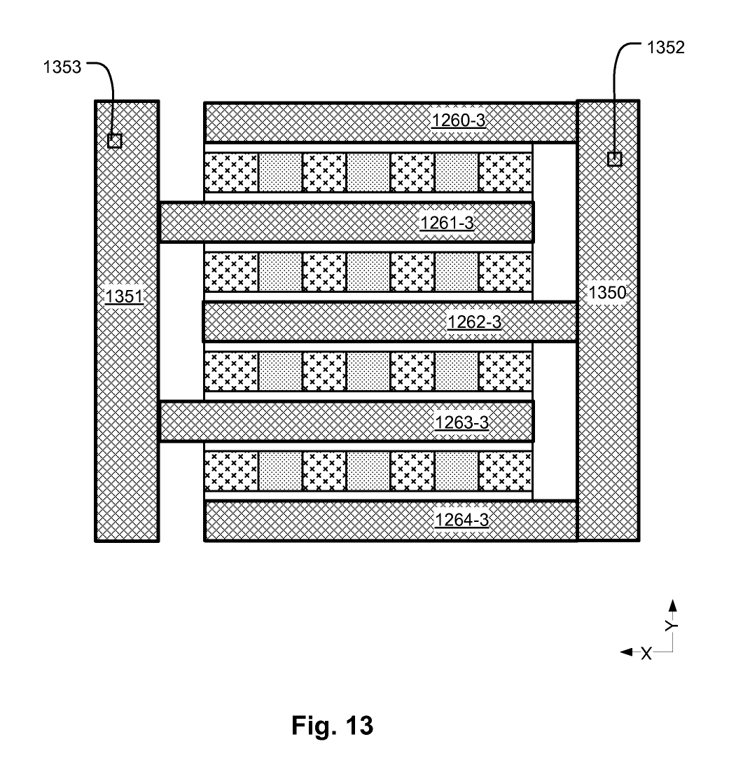

FIG. 13 shows a layout view of a level in an alternate embodiment, showing left side and right side conductors 1260-3 to 1264-3 from the top level of FIG. 4 coupled together with extensions 1350, 1351 (also called pads) for connection of the left side and right side conductors (1260-3 to 1264-3) to the left and right plane decoders. As can be seen, the left side conductors 1261-3 and 1263-3 are coupled to an extension 1351 which is adapted for connection to a contact plug on a landing area 1353, through which connection via overlying patterned conductor layers to a decoder circuit can be made. Likewise, right side conductors 1260-3, 1262-3 and 1264-3 are coupled to an extension 1350 which is adapted for connection to a contact plug on landing area 1352, through which connection to a decoder circuit can be made.

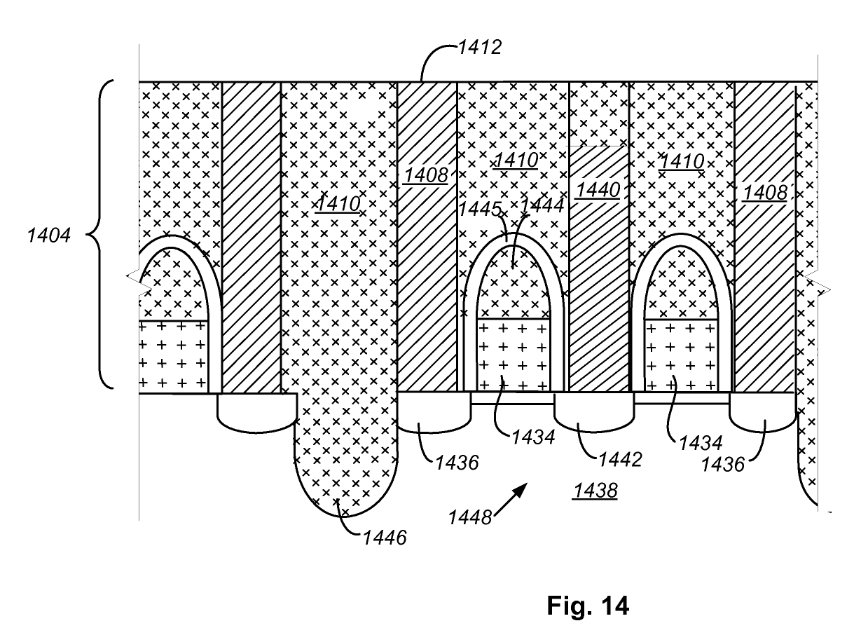

FIG. 14 shows one example implementation for an array of access devices suitable for use as the pillar access device array shown in FIG. 1. As shown in FIG. 14, an access layer 1404 is implemented in a substrate including insulating material 1410, having a top surface with an array of contacts (e.g. contact 1412) exposed thereon. The contacts for individual pillars are provided at top surfaces of drain contacts 1408, which are coupled to the drain terminals (e.g. 1436) of MOS transistors in the access layer. The access layer 1404 includes a semiconductor body having source regions 1442 and drain regions 1436 therein. Polysilicon word lines 1434 are provided over gate dielectric layers and between the source regions 1442 and drain regions 1436. In the embodiment shown, the source regions 1442 are shared by adjacent MOS transistors, making two-transistor structures 1448. Source contacts 1440 are positioned between word lines 1434 and contact source regions 1442 within substrate 1438. The source contacts 1440 can be connected to bit lines (not shown) in a metal layer, which run perpendicular to the word lines and between the columns of drain contacts 1408. Word lines 1434 are covered by silicide caps 1444. Word lines 1434 and caps 1444 are covered by a dielectric layer 1445. Isolation trenches 1446 separate the two-transistor structures 1448 from the adjacent two-transistor structures. In this example transistors act as the access devices. Individual pillars can be coupled to the contacts 1412, and selected individually by controlling the biasing of the source contacts 1440 and the word lines 1434. Of course other structures may be used to implement the access device array, including for example, vertical MOS device arrays.

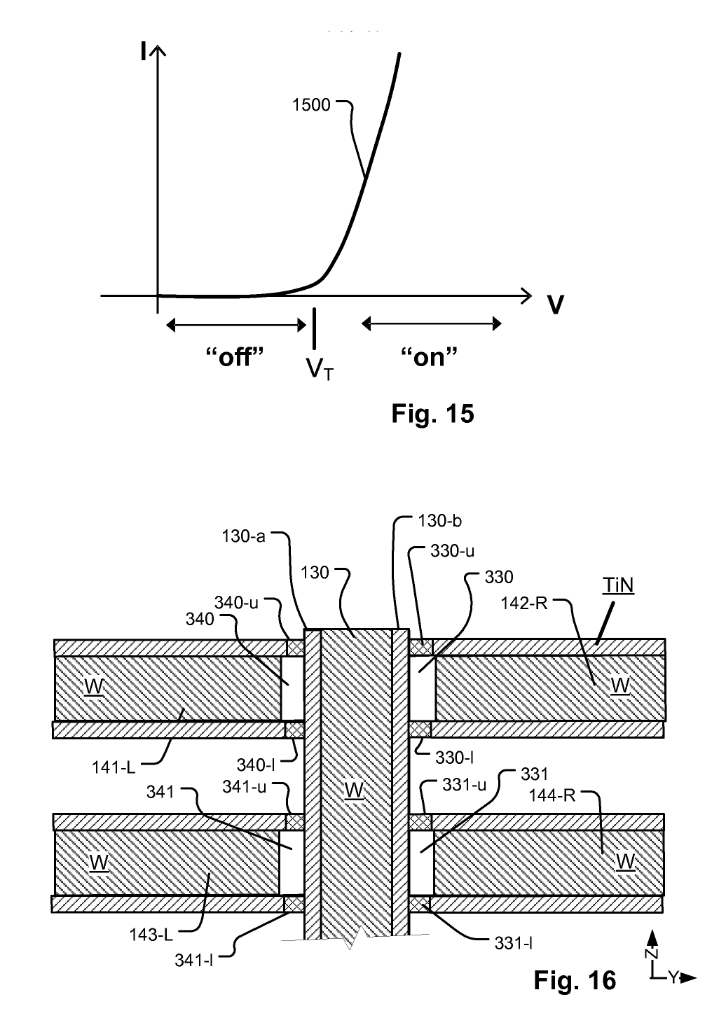

FIG. 15 is a graph of current versus voltage (IV curve) for transition metal oxide memory element, comprising for example tungsten oxide. The IV curve 1500 shows non-linear property that can be relied upon in place of a separate switching element for the memory cells. As can be seen, below a threshold voltage V_{T}, the metal oxide material essentially blocks current flow and is “off,” while above the threshold voltage V_{T}, the metal oxide material allows current flow and is “on.” Thus, metal oxides and other memory materials exhibiting this characteristic can rely on built-in self-switching.

FIG. 16 illustrates an alternative to the two-cell structure illustrated in FIG. 3B, deploying metal oxide memory cell technology, like that described in U.S. Pat. No. 8,279,656, which is incorporated by reference as if fully set forth herein. FIG. 16 shows (utilizing the same reference numerals as FIG. 3B, where appropriate) a side view of two-unit cells in two levels of the 3D array, where the top two-unit cell includes left side conductor 141-L and side wall memory element 340 connected to the pillar 130, and memory element 330 on the opposing side of the pillar 130, and right side conductor 142-R. The two-unit cell in the second level includes a two-unit cell including left side conductor 143-L and side wall memory element 341 connected to the pillar 130, and memory element 331 on the opposing side of the pillar 130, and right side conductor 144-R. In the alternative illustrated in FIG. 16, the conductors 141-L, 142-R, 143-L and 144-R are multilayer conductors, including a liner of a different oxidizable material such as titanium nitride TiN, which can oxidize at a slower rate than the bulk material, such as tungsten W. In this manner, when the conductor layers are oxidized to form the memory elements, the tungsten core oxidizes to a greater depth (in the horizontal direction in this example) than does the bulk material of the conductive layer, forming TiNOₓ in the TiN liner example, in upper and lower regions 340-u, 340-1, 341-u, 341-1, 330-u, 330-1, 331-u and 331-1, of the sidewall cross-points in which the memory cells are formed. Also, the pillar 130 can comprise a tungsten core with TiN liners 130-a and 130-b as illustrated.

As mentioned above, in some implementations, there can be more than two levels, such as eight levels, sixteen levels and so on. The memory element 340 is over the memory element 341, both of which are disposed on a sidewall of the pillar 130. Likewise, memory element 330 is over memory element 331, both of which are disposed on a sidewall of the pillar 130.

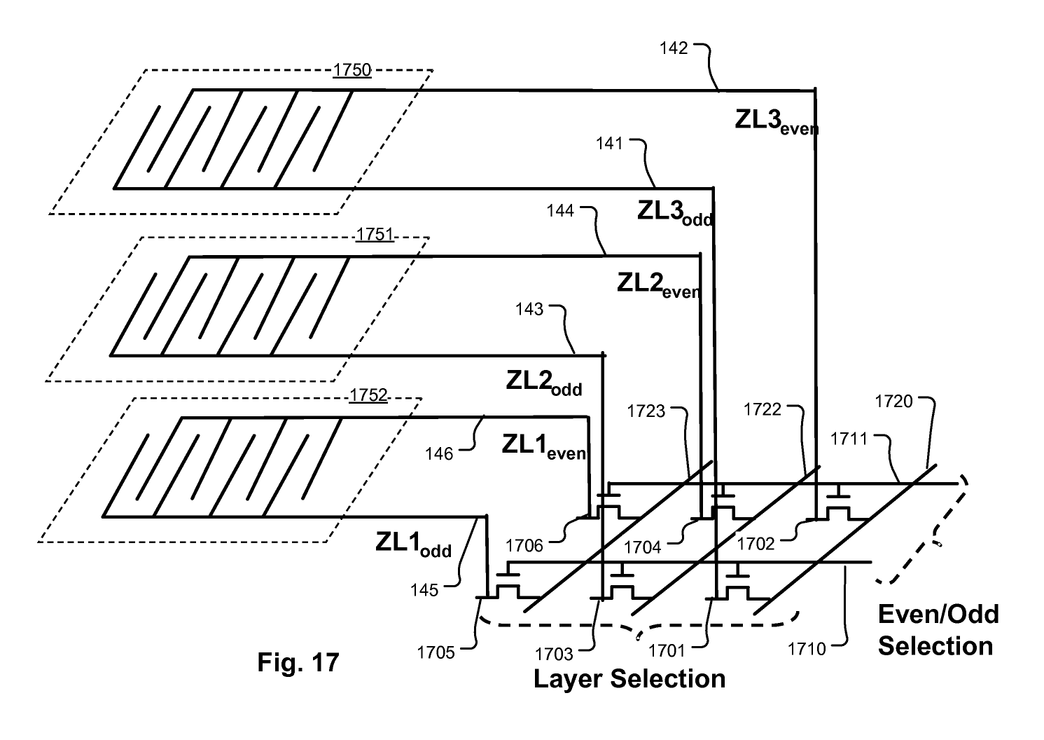

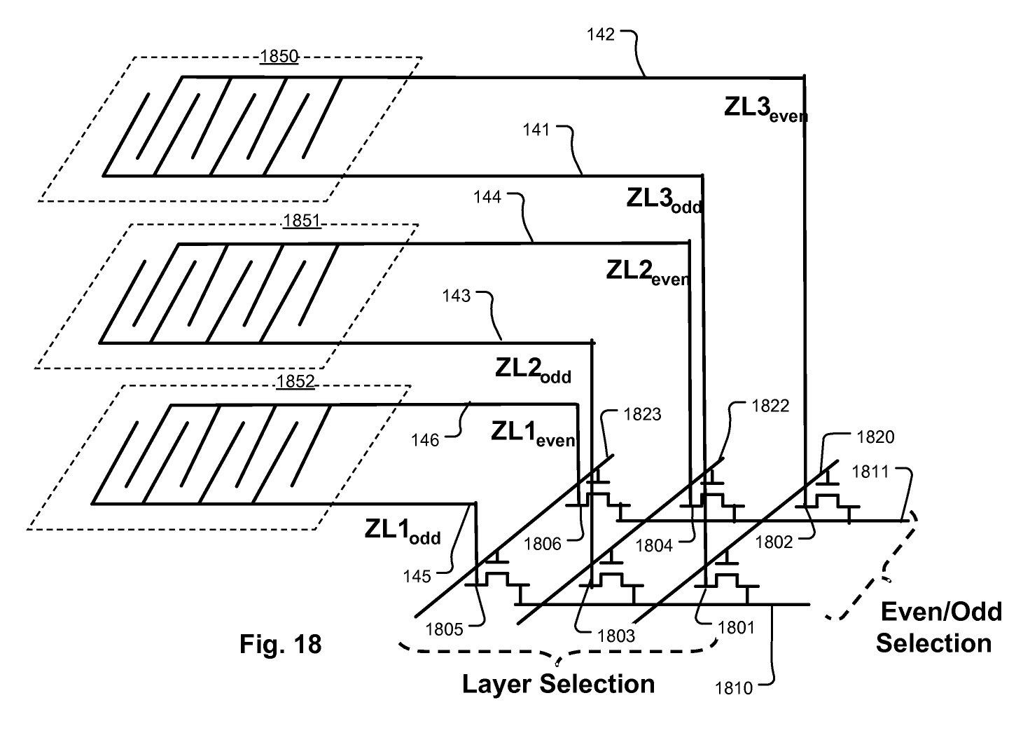

FIGS. 17 and 18 show alternate arrangements for decoding circuitry to provide left/right and level decoding for the left and right conductors in the memory structures described herein. In FIG. 17, the 3D array is schematically represented by the levels 1750-1752 including the interleaved left and right conductors, called even and odd conductors 141, 142 for level 1750, even and odd conductors 143, 144 for level 1751, and even and odd conductors 145, 146 for level 1752. Decoding circuitry includes transistors having gates coupled to even/odd selection lines 1710 and 1711, sources coupled to layer selection lines 1720, 1722 and 1723, and drains coupled to the pads in the various levels, at contacts 1701-1706.

In FIG. 18, the 3D array is schematically represented by the levels 1850-1852 including the interleaved left and right conductors, called even and odd conductors 141, 142 for level 1850, even and odd conductors 143, 144 for level 1851, and even and odd conductors 145, 146 for level 1852. Decoding circuitry includes transistors having sources coupled to even/odd selection lines 1810 and 1811, gates coupled to layer selection lines 1820, 1822 and 1823, and drains coupled to the pads in the various levels, at contacts 1801-1806.

A decoding method to access a specific cell can include turning on the slice select line and column select line in the access circuits coupled to the pillars, to select a particular pillar, while using the level select and even/odd select lines to select a particular cell on the selected pillar, applying the appropriate bias voltage for read, program or erase across the selected pillar and even/odd select lines.

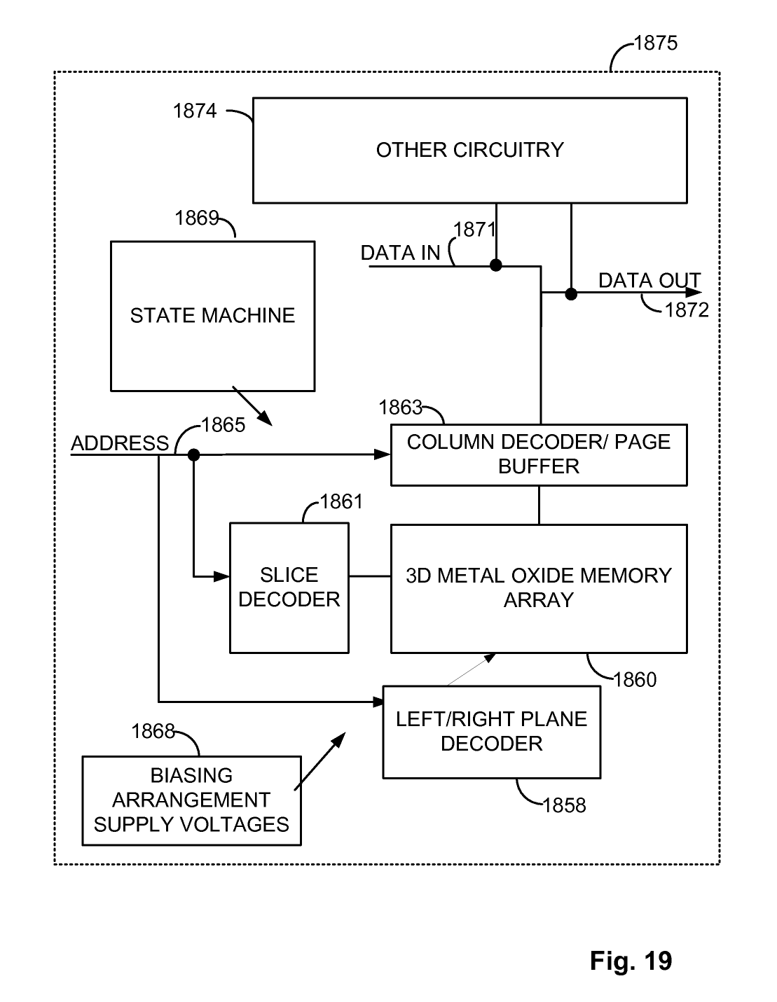

FIG. 19 is a simplified block diagram of an integrated circuit according to an embodiment of the present invention. The integrated circuit 1875 includes a 3D two-cell unit structure metal oxide memory array 1860, implemented as described herein, on a substrate. Addresses are supplied on bus 1865 to column decoder/page buffer circuits 1863, slice decoder 1861 and left/right plane decoder 1858. An array of access devices for individual pillars underlies the array 1860, and is coupled to the slice decoder 1861 and the column decoder/page buffer circuits 1863, for array embodiments like that shown in FIG. 1. Data is supplied via the data-in line 1871 from input/output ports on the integrated circuit 1875 or from other data sources internal or external to the integrated circuit 1875, to the column decoder/page buffer circuits 1863. In the illustrated embodiment, other circuitry 1874 is included on the integrated circuit, such as a general purpose processor or special purpose application circuitry, or a combination of modules providing system-on-a-chip functionality supported by the memory cell array. Data is supplied via the data-out line 1872 from the column decoder/page buffer circuits 1863 to input/output ports on the integrated circuit 1875, or to other data destinations internal or external to the integrated circuit 1875.

A controller implemented in this example using bias arrangement state machine 1869 controls the application of bias arrangement supply voltages generated or provided through the voltage supply or supplies in block 1868, such as read, program and erase voltages. The controller can be implemented using special-purpose logic circuitry as known in the art. In alternative embodiments, the controller comprises a general-purpose processor, which may be implemented on the same integrated circuit, which executes a computer program to control the operations of the device. In yet other embodiments, a combination of special-purpose logic circuitry and a general-purpose processor may be utilized for implementation of the controller.

Three-dimensional stacking is an efficient way to reduce the cost per bit for semiconductor memory, particularly when physical limitations in the size of the memory elements is reached for a given plane. Prior art technology addressed to 3D arrays requires several critical lithography steps to make minimum feature size elements in each stack layer. Also, driver transistors used for the memory array multiplied in number by the number of planes.

Technology described here includes a high density 3D array in which only one critical layer lithography step is required to pattern all the layers. The memory via and layer interconnect via patterning steps shared by each layer. Also, the layers can share the word line and bit line decoders to reduce the area penalty of prior art multilevel structures. Also, a unique two-2-cell unit structure is described for metal oxide and other programmable resistance memory in which data sites are provided on each of two sides of a memory pillar. An array of access devices is used to select individual memory pillars. Left and right word lines are used to select individual cells on selected planes.

While the present invention is disclosed by reference to the preferred embodiments and examples detailed above, it is to be understood that these examples are intended in an illustrative rather than in a limiting sense. It is contemplated that modifications and combinations will readily occur to those skilled in the art, which modifications and combinations will be within the spirit of the invention and the scope of the following claims.

What is claimed is:

1. A memory device, comprising:
an array of access devices;
a plurality of patterned conductor layers, separated from each other and from the array of access devices by insulating layers, the plurality of patterned conductor layers including left side and right side conductors;
an array of conductive pillars extending through the plurality of patterned conductor layers, the conductive pillars in the array contacting corresponding access devices in the array of access devices, and defining left side and right side interface regions between the conductive pillars and adjacent left side and right side conductors in corresponding patterned conductor layers in the plurality of patterned conductor layers; and
memory elements in the left side and right side interface regions, each of said memory elements comprising a programmable and erasable memory material.

2. The memory device of claim 1, including:
row decoding circuits and column decoding circuits coupled to the array of access devices arranged to select a conductive pillar in the array of conductive pillars; and
left and right plane decoding circuits coupled to the left side and right side conductors in the plurality of patterned conductor layers arranged to turn on current flow in a selected cell in a left side or right side interface region in a selected patterned conductor layer and to turn off current flow in an unselected cell.

3. The memory device of claim 1, wherein a conductive pillar in the array of conductive pillars comprises a conductor in electrical communication with a corresponding access device, and a layer of memory material between the conductor and the plurality of patterned conductor layers, wherein the programmable element in each of said memory elements comprises an active region in the layer of memory material at the interface regions.

4. The memory device of claim 1, wherein an access device in the array of access devices comprises:
a transistor having a gate, a first terminal and a second terminal; and
the array including a bit line coupled to the first terminal, a word line coupled to the gate, and wherein the second terminal is coupled to a corresponding conductive pillar in the array of conductive pillars.

5. The memory device of claim 1, wherein an access device in the array of access devices comprises a vertical transistor having a first source/drain terminal coupled to a corresponding conductive pillar in the array of conductive pillars; and
the array including a source line or bit line coupled to source/drain terminal of the vertical transistor, and a word line providing a surrounding gate structure.

6. The memory device of claim 1, wherein a conductive pillar in the array of conductive pillars of said electrode material comprises a metal, a metal nitride or a combination of metal and metal nitride, the plurality of patterned conductor layers comprise a metal, and the transition metal oxide in the interface regions is characterized by built in self-switching.

7. The memory device of claim 1, wherein the left side and right side conductors in the plurality of patterned conductor layers are configured for contact to corresponding left side and right side plane decoding circuitry.

8. The memory device of claim 1, wherein the array of access devices underlie the plurality of patterned conductor layers.

9. The memory device of claim 1, wherein:
the left side and right side conductors in each layer have landing areas that are not overlaid by any of the left side and right side conductors in overlying patterned conductor layers; and including:
conductive lines extending through the plurality of conductor layers and contacting the landing areas, and
left side and right side connectors over the plurality of patterned conductor layers and in contact with the conductive lines; and
left and right plane decoding circuits coupled to the left side and right side connectors.

10. The memory device of claim 1, wherein the memory elements comprise transition metal oxide characterized by built in self-switching.

11. A memory device, comprising:
a plurality of bit lines in a first plane;
a plurality of select lines in a second plane parallel with the first plane;
an array of pillar select devices, the access devices in the array being disposed at corresponding cross-points of the plurality of bit lines and select lines, each having a first terminal connected to a bit line at the corresponding cross-point, a second terminal connected to a select line at the corresponding cross-point, and a third terminal;
an array of conductive pillars, conductive pillars in the array being connected to the third terminal of a corresponding access device in the array of access devices;
a 3D array of sidewall memory elements comprising transition metal oxide characterized by built in self-switching, the sidewall memory elements in the 3D array disposed on sides of the conductive pillars in the array, including a plurality of sidewall memory elements on each pillar, the sidewall memory elements in the 3D array comprising programmable and erasable memory material;
a plurality of pairs of word line structures orthogonal to the array of conductive pillars, each pair being disposed at a corresponding level of the 3D array, and a given pair of word line structures in a level including:
a first word line structure including a first set of word lines coupled together at a first word line pad for the level, each word line in the first set being connected to side wall memory elements between alternating rows of conductive pillars in said array of conductive pillars; and
a second word line structure including a second set of word lines coupled together at a second word line pad for the level, and interleaved with the word lines in the first set of word lines, each word line in the first set being connected to side wall memory elements between alternating rows of conductive pillars in said array of conductive pillars.

12. The memory device of claim 11, including address decoding circuitry coupled to the plurality of bit lines for accessing a column of conductive pillars, coupled to the plurality of select lines for accessing a slice of conductive pillars orthogonal to the column, and coupled to the plurality of pairs of word line structures for accessing a level of cells in the 3D array.

13. The memory device of claim 11, wherein the 3D array of sidewall memory elements includes a plurality of two-cell unit structures on each of the pillars, the two-cell unit structures on a given pillar including a memory element along a first side and connected with a word line in the first set of word lines for the level, and a second memory element along a second opposing side and connected with a word line in the second set of word lines for the level.

14. The memory device of claim 11, wherein said sidewall memory elements include programmable resistance memory material.

15. The memory device of claim 11, wherein said sidewall memory elements include programmable resistance, metal oxide memory material characterized by built in self switching.

16. The memory device of claim 11, wherein said sidewall memory elements include programmable resistance, tungsten oxide memory material.

17. The memory device of claim 11, further comprising a controller to program and erase selected memory cells.

18. A method for manufacturing a memory device, comprising:
forming an array of access devices;
forming a plurality of patterned conductor layers, separated from each other and from the array of access devices by insulating layers, the plurality of patterned conductor layers including left side and right side conductors;
forming an array of conductive pillars extending through the plurality of patterned conductor layers, the conductive pillars in the array contacting corresponding access devices in the array of access devices, and defining left side and right side interface regions between the conductive pillars and the left side and right side conductors in corresponding patterned conductor layers in the plurality of patterned conductor layers; and
forming memory elements in the left side and right side interface regions, each of said memory elements comprising a transition metal oxide, by oxidizing the left side and right side conductors in each layer.

19. The method of claim 18, wherein said forming a plurality of patterned conductor layers includes:
forming a plurality of blanket layers of conductive material;
forming blanket layers of insulating material between the blanket layers of conductive material to form a stack; and
etching the stack including the plurality of blanket layers to define the left side and right side conductors.

20. The method of claim 19, wherein said etching the stack includes etching trenches through the plurality of patterned conductor layers, and said forming an array of conductive pillars includes:
forming the a transition metal oxide on sidewalls of the trenches;
filling the trenches over the transition metal oxide on the sidewalls with an electrode material; and
patterning the electrode material within the trenches to form the array of conductive pillars.

21. The method of claim 20, wherein said electrode material comprises a metal nitride.

22. The method of claim 18, including patterning the plurality of patterned conductor layers so that the left side and right side conductors in each layer have landing areas that are not overlaid by any of the left side and right side conductors in overlying patterned conductor layers, forming vias exposing the landing areas, forming conductive lines in the vias, and forming connectors over the plurality of patterned conductor layers and in contact with the conductive lines in the vias, the connectors adapted for connection to decoding circuitry.

23. The method of claim 18, wherein the transition metal oxide in the interface regions is characterized by built in self-switching.
